(19) United States
(12) Patent Application Publication
(10) Pub. No.: US 2025/0087251 A1
(43) Pub. Date: Mar. 13, 2025

(54) Power-Gate Structure

(71) Applicant: Arm Limited, Cambridge (GB)

(72) Inventors: Rahul Mathur, Austin, TX (US); Andy Wangkun Chen, Austin, TX (US)

(21) Appl. No.: 18/367,902

(22) Filed: Sep. 13, 2023

(51) Int. Cl. G11C 5/14

(52) U.S. Cl. CPC G11C 5/148

(57) ABSTRACT

Various implementations described herein are directed to a device having a power-gate structure with multiple transistors including a first transistor and a second transistor. The first transistor may be coupled between a first voltage node and a second voltage node, and the second transistor may be coupled between the second voltage node and a third voltage node that is coupled to the second voltage node.

### BACKGROUND

This section is intended to provide information relevant to understanding the various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In some modern circuit architectures, deficiencies can arise when implementing power-gate schemes to power-off certain portions of logic during sleep mode to save static power. Sometimes, power gates can be placed internally within a memory macro to power down certain portions of memory logic during sleep modes. For instance, a header based power-gate is used to cut-off external power from internal memory logic using a transistor during sleep modes. Also, a footer based power-gate is used to cut-off an external ground from internal memory logic using a transistor during sleep modes. Unfortunately, internal power and ground grids may suffer from dynamic IR drop during simultaneous toggling of large logic gate structures, such as, e.g., memory logic, including wordline drivers, data output drivers, etc. As such, this may adversely impact performance of critical paths, and thus, there exists a need to mitigate dynamic IR drop on power grids in modern circuitry by providing more effective power-gate schemes for circuit based applications.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIG. 1 illustrates a diagram of a header based power-gate structure with a common-gate in accordance with various implementations described herein.

FIG. 2 illustrates a diagram of a header based power-gate structure with a split-gate in accordance with various implementations described herein.

FIG. 3 illustrates a diagram of a footer based power-gate structure with a common-gate in accordance with various implementations described herein.

FIG. 4 illustrates a diagram of a footer based power-gate structure with a split-gate in accordance with various implementations described herein.

FIG. 5 illustrates a diagram of a header-footer based power-gate structure for a circuit in accordance with various implementations described herein.

FIG. 6 illustrates a diagram of a header-footer based power-gate structure for multiple circuits in accordance with various implementations described herein.

### DETAILED DESCRIPTION

Various implementations described herein are related to multi-transistor power-gate schemes and techniques for circuit related applications in physical designs. Also, in some implementations, multi-transistor power-gate schemes and techniques described herein provide for CFET (complementary field effect transistor) designs that improve area and performance of circuit designs, such as memory. Also, in some implementations, the multi-transistor power-gate schemes and techniques described herein provide for various novel area-efficient complementary field effect (CFET) power-gate designs with dynamic IR drop mitigation on internal power grids and/or or ground grids for circuit applications, including memory based circuit applications. Also, in various implementations, the multi-transistor power-gate schemes and techniques described herein provide for header based power-gate applications, footer based power-gate applications, and/or some combination of header and footer based applications. Also, in some implementations, in reference to buried power rail (BPR) technology, one or more voltage supply nets may be buried so as to comprise a buried voltage supply net, a buried power rail, or similar.

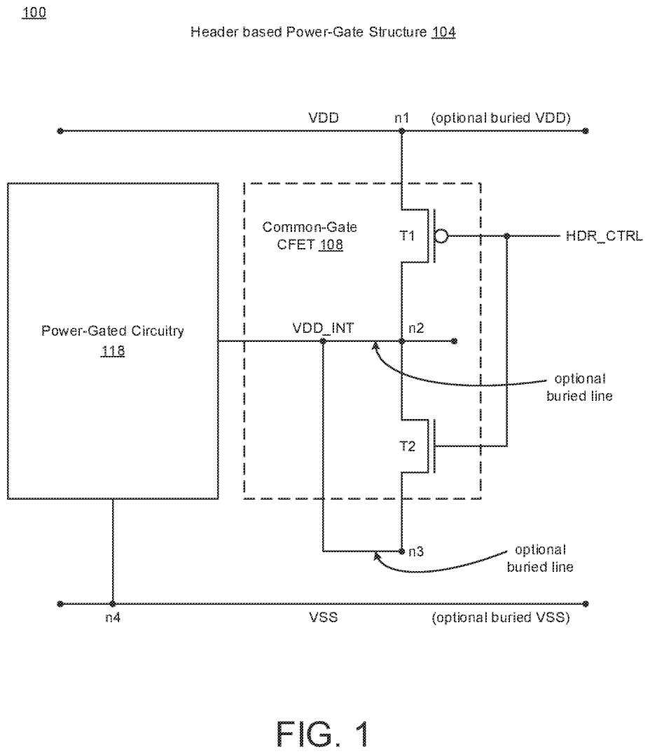

Various implementations of multi-transistor bitcell schemes and techniques for circuit based applications will now be described herein in FIGS. 1-6.

FIG. 1 illustrates a diagram 100 of a header based power-gate structure 104 with a common-gate in accordance with various implementations described herein.

In various implementations, the header based power-gate structure 104 may provide for fabricating multi-transistor related circuitry with various integrated circuit (IC) components that are arranged and/or coupled together as an assemblage or some combination of parts that may provide for physical circuit designs and structures. In some instances, a method of designing, providing and fabricating the power-gate structure 104 as an integrated device may involve use of various circuit components and/or related structures described herein so as to implement various multi-transistor bitcell techniques associated therewith. Also, the power-gate structure 104 may be integrated with various circuitry and/or related components on a single chip, and also, the power-gate structure 104 may be implemented in some embedded devices for automotive, mobile, computer, server and/or Internet-of-Things (IoT) based applications.

As shown in FIG. 1, the header based power-gate structure 104 may include a plurality of transistors (e.g., T1, T2), including, e.g., a first transistor (T1) and a second transistor (T2) that are arranged and coupled together so as to operate and/or function as a multi-transistor power-gate structure, such as a 2-transistor (2T) power-gate structure for various circuit related applications. In various applications, the first transistor (T1) may be coupled between a first voltage node (n1) and a second voltage node (n2), and also, the second transistor (T2) may be coupled between the second voltage node (n2) and a third voltage node (n3) that is coupled to the second voltage node (n2).

In some implementations, the first voltage node (n1) may comprise a positive voltage supply (VDD), such as, e.g., a positive power supply rail, and the second voltage node (n2) may comprise an intermediate voltage supply (VDD_INT) based on the positive voltage supply (VDD). Also, the intermediate voltage supply (VDD_INT) may be referred to as an intermediate power supply rail. Also, in various instances, the second transistor (T2) may operate to add capacitance to the intermediate voltage supply (VDD_INT) at the second voltage node (n2).

In some implementations, the header based power-gate structure 104 may be coupled to power-gated circuitry 118, wherein the power-gated circuitry 118 is coupled between the intermediate voltage supply (VDD_INT) at the second voltage node (n2) and a ground voltage supply (VSS or GND) at node (n4). Thus, the header based power-gate structure 104 may be used to power-gate the power-gated circuitry 118 via the first voltage node (n1) and the second voltage node (n2) with the positive voltage supply (VDD). Also, in some implementations, in reference to buried power rail (BPR) technology, one or more of the voltage supply nets (e.g., n1, n2, n3, n4) may be buried so as to comprise a buried voltage supply net, a buried power rail, or similar.

In some implementations, the first transistor (T1) and the second transistor (T2) may include a common-gate (CG) configuration 108 such that the first transistor (T1) and the second transistor (T2) share a common gate that is coupled to a control signal, such as, e.g., a header control signal (HDR_CTRL). In some instances, as shown in FIG. 1, the header based power-gate structure 104 may comprise a header (HDR) that operates to power-gate a circuit, such as, e.g., the power-gated circuitry 118 by way of the header control signal (HDR_CTRL) that is used to activate and deactivate the first transistor (T1) and the second transistor (T2). Also, as shown, the header control signal (HDR_CTRL) may be coupled to gates of the first transistor (T1) and the second transistor (T2).

In various implementations, as shown in FIG. 1, the first transistor (T1) may comprise a P-type transistor, and the second transistor (T2) may be an N-type transistor, and also, the first transistor (T1) and the second transistor (T2) may be formed with a complementary field effect transistor (CFET) technology such that the P-type transistor (T1) is physically disposed on the N-type transistor (T2) in a P-over-N (PN) configuration or such that the N-type transistor is physically disposed on the P-type transistor in an N-over-P (NP) configuration, in various circuit based applications. However, various other configurations may be used and/or implemented to achieve similar results and/or behavior, wherein in some instances, the N-type transistor is physically disposed on the P-type transistor in an N-over-P (NP) configuration.

In some implementations, as shown in FIG. 1, the header based power-gate structure 104 may be implemented with a multi-transistor structure, such as, e.g., a two-transistor (2T) related structure. Also, the multi-transistor structure may be configured a P-type metal-oxide-semiconductor (PMOS) transistor as the first transistor (T1) and an N-type MOS (NMOS) transistor as the second transistor (T2). Also, the first transistor (T1) may refer to a P-type field-effect transistor (PFET), and the second transistor (T2) refer to an N-type FET (NFET) transistor. However, various other configurations may be used to achieve similar results, behaviors and/or characteristics.

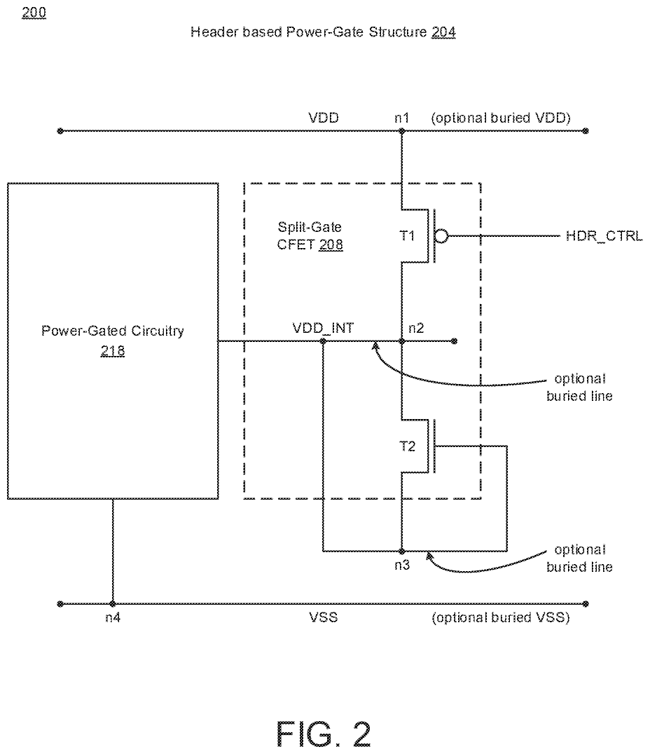

FIG. 2 illustrates a diagram 200 of a header based power-gate structure 204 with a split-gate in accordance with various implementations described herein.

In various implementations, the header based power-gate structure 204 may provide for fabricating multi-transistor related circuitry with various integrated circuit (IC) components that are arranged and/or coupled together as an assemblage or some combination of parts that may provide for physical circuit designs and structures. In some instances, a method of designing, providing and fabricating the power-gate structure 204 as an integrated device may involve use of various circuit components and/or related structures described herein so as to implement various multi-transistor bitcell techniques associated therewith. Also, the power-gate structure 204 may be integrated with various circuitry and/or related components on a single chip, and also, the power-gate structure 204 may be implemented in some embedded devices for automotive, mobile, computer, server and/or Internet-of-Things (IoT) based applications.

As shown in FIG. 2, the header based power-gate structure 204 may include a plurality of transistors (e.g., T1, T2), including, e.g., the first transistor (T1) and also the second transistor (T2) that are arranged and coupled together so as to operate and/or function as a multi-transistor power-gate structure, such as a 2T power-gate structure for various circuit related applications. In some applications, the first transistor (T1) may be coupled between the first voltage node (n1) and the second voltage node (n2), and also, the second transistor (T2) may be coupled between the second voltage node (n2) and the third voltage node (n3) that is coupled to the second voltage node (n2).

In some implementations, the first voltage node (n1) may comprise the positive voltage supply (VDD), such as, e.g., a positive power supply rail, and the second voltage node (n2) may comprise the intermediate voltage supply (VDD_INT) based on the positive voltage supply (VDD). Also, the intermediate voltage supply (VDD_INT) may be referred to as an intermediate power supply rail. Also, in various instances, the second transistor (T2) may operate to add capacitance to the intermediate voltage supply (VDD_INT) at the second voltage node (n2).

In some implementations, the header based power-gate structure 204 may be coupled to power-gated circuitry 218, wherein the power-gated circuitry 218 is coupled between the intermediate voltage supply (VDD_INT) at the second voltage node (n2) and the ground voltage supply (VSS or GND) at node (n4). Thus, header based power-gate structure 204 may be used to power-gate the power-gated circuitry 218 via the first voltage node (n1) and the second voltage node (n2) with the positive voltage supply (VDD). Also, in some implementations, in reference to buried power rail (BPR) technology, one or more of the voltage supply nets (e.g., n1, n2, n3, n4) may be buried so as to comprise a buried voltage supply net, a buried power rail, or similar.

In some implementations, the first transistor (T1) and the second transistor (T2) may include a split-gate (SG) configuration 208 such that a gate of the first transistor (T1) is coupled to a control signal, such as, e.g., header control signal (HDR_CTRL), and such that a gate of the second transistor (T2) is coupled to the third voltage node (n3). In some instances, the second transistor (T2) is coupled together to operate as a capacitor. Also, in some instances, as shown in FIG. 2, the header based power-gate structure 204 may comprise a header (HDR) that operates to power-gate a circuit, such as, e.g., the power-gated circuitry 218 by way of header control signal (HDR_CTRL) that is used to activate and deactivate the first transistor (T1). Also, the header control signal (HDR_CTRL) may be coupled to the gate of the first transistor (T1).

In various implementations, as shown in FIG. 2, the first transistor (T1) may comprise a P-type transistor, and the second transistor (T2) may be an N-type transistor, and also, the first transistor (T1) and the second transistor (T2) may be formed with a complementary field effect transistor (CFET) technology such that the P-type transistor (T1) is physically disposed on the N-type transistor (T2) in a P-over-N (PN) configuration or such that the N-type transistor is physically disposed on the P-type transistor in an N-over-P (NP) configuration, in various circuit based applications. However, various other configurations may be used and/or implemented to achieve similar results and/or behavior, wherein in some instances, the N-type transistor is physically disposed on the P-type transistor in an N-over-P (NP) configuration.

In some implementations, as shown in FIG. 2, the header based power-gate structure 204 may be implemented with a multi-transistor structure, such as, e.g., a two-transistor (2T) related structure. Also, the multi-transistor structure may be configured a P-type metal-oxide-semiconductor (PMOS) transistor as the first transistor (T1) and an N-type MOS (NMOS) transistor as the second transistor (T2). Also, the first transistor (T1) may refer to a P-type field-effect transistor (PFET), and the second transistor (T2) refer to an N-type FET (NFET) transistor. However, various other configurations may be used to achieve similar results, behaviors and/or characteristics.

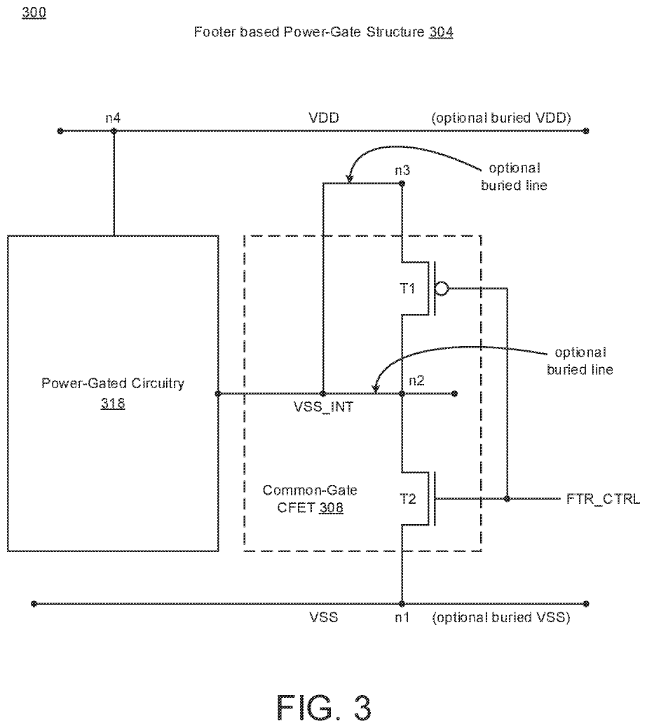

FIG. 3 illustrates a diagram 300 of a footer based power-gate structure 304 with a common-gate in accordance with various implementations described herein.

In various implementations, the footer based power-gate structure 304 may provide for fabricating multi-transistor related circuitry with various integrated circuit (IC) components that are arranged and/or coupled together as an assemblage or some combination of parts that may provide for physical circuit designs and structures. In some instances, a method of designing, providing and fabricating the power-gate structure 304 as an integrated device may involve use of various circuit components and/or related structures described herein so as to implement various multi-transistor bitcell techniques associated therewith. Also, the power-gate structure 304 may be integrated with various circuitry and/or related components on a single chip, and also, the power-gate structure 304 may be implemented in some embedded devices for automotive, mobile, computer, server and/or Internet-of-Things (IoT) based applications.

As shown in FIG. 3, the footer based power-gate structure 304 may include a plurality of transistors (e.g., T1, T2), including the first transistor (T1) and the second transistor (T2) that are arranged and coupled together so as to operate and/or function as a multi-transistor power-gate structure, such as a 2-transistor (2T) power-gate structure for various circuit related applications. In various applications, the first transistor (T1) may be coupled between a first voltage node (n1) and a second voltage node (n2), and also, the second transistor (T2) may be coupled between the second voltage node (n2) and a third voltage node (n3) that is coupled to the second voltage node (n2).

In various implementations, the first voltage node (n1) may comprise a ground voltage supply (VSS or GND), such as, e.g., a ground supply rail, and the second voltage node (n2) may comprise an intermediate voltage supply (VSS_INT) based on the ground voltage supply (VSS or GND). Also, the intermediate voltage supply (VSS_INT) may be referred to as an intermediate power supply rail. Also, in various instances, the second transistor (T2) may operate to add capacitance to the intermediate voltage supply (VSS_INT) at the second voltage node (n2).

In various implementations, the footer based power-gate structure 304 may be coupled to power-gated circuitry 318, wherein the power-gated circuitry 318 is coupled between the intermediate voltage supply (VSS_INT) at the second voltage node (n2) and the positive voltage supply (VDD) at node (n4). Therefore, the footer based power-gate structure 304 may be used to power-gate the power-gated circuitry 318 via the first voltage node (n1) and the second voltage node (n2) with the ground voltage supply (VSS). Also, in some implementations, in reference to buried power rail (BPR) technology, one or more of the voltage supply nets (e.g., n1, n2, n3, n4) may be buried so as to comprise a buried voltage supply net, a buried power rail, or similar.

In some implementations, the first transistor (T1) and the second transistor (T2) may include a common-gate (CG) configuration 308 such that the first transistor (T1) and the second transistor (T2) share a common gate that is coupled to a control signal, such as, e.g., a footer control signal (FTR_CTRL). In some instances, as shown in FIG. 3, the footer based power-gate structure 304 may comprise a footer (FTR) that operates to power-gate a circuit, such as, e.g., the power-gated circuitry 318 by way of footer control signal (FTR_CTRL) that is used to activate and deactivate the first transistor (T1) and the second transistor (T2). Also, as shown, the footer control signal (FTR_CTRL) may be coupled to gates of the first transistor (T1) and the second transistor (T2).

In various implementations, as shown in FIG. 3, the first transistor (T1) may comprise a P-type transistor, and the second transistor (T2) may be an N-type transistor, and also, the first transistor (T1) and the second transistor (T2) may be formed with a complementary field effect transistor (CFET) technology such that the P-type transistor (T1) is physically disposed on the N-type transistor (T2) in a P-over-N (PN) configuration or such that the N-type transistor is physically disposed on the P-type transistor in an N-over-P (NP) configuration, in various circuit based applications. However, various other configurations may be used and/or implemented to achieve similar results and/or behavior, wherein in some instances, the N-type transistor is physically disposed on the P-type transistor in an N-over-P (NP) configuration.

In some implementations, as shown in FIG. 3, the footer based power-gate structure 304 may be implemented with a multi-transistor structure, such as, e.g., a two-transistor (2T) related structure. Also, the multi-transistor structure may be configured a P-type metal-oxide-semiconductor (PMOS) transistor as the first transistor (T1) and an N-type MOS (NMOS) transistor as the second transistor (T2). Also, the first transistor (T1) may refer to a P-type field-effect transistor (PFET), and the second transistor (T2) refer to an N-type FET (NFET) transistor. However, various other configurations may be used to achieve similar results, behaviors and/or characteristics.

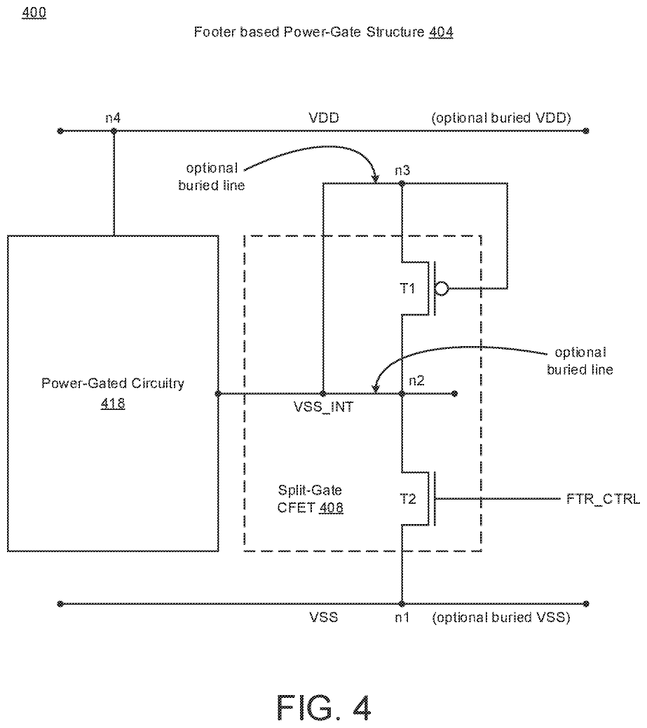

FIG. 4 illustrates a diagram 400 of a footer based power-gate structure 404 with a split-gate in accordance with various implementations described herein.

In various implementations, the footer based power-gate structure 404 may provide for fabricating multi-transistor related circuitry with various integrated circuit (IC) components that are arranged and/or coupled together as an assemblage or some combination of parts that may provide for physical circuit designs and structures. In some instances, a method of designing, providing and fabricating the power-gate structure 404 as an integrated device may involve use of various circuit components and/or related structures described herein so as to implement various multi-transistor bitcell techniques associated therewith. Also, the power-gate structure 404 may be integrated with various circuitry and/or related components on a single chip, and also, the power-gate structure 404 may be implemented in some embedded devices for automotive, mobile, computer, server and/or Internet-of-Things (IoT) based applications.

As shown in FIG. 4, the footer based power-gate structure 404 may include a plurality of transistors (e.g., T1, T2), including, e.g., the first transistor (T1) and also the second transistor (T2) that are arranged and coupled together so as to operate and/or function as a multi-transistor power-gate structure, such as a 2T power-gate structure for various circuit related applications. In some applications, the first transistor (T1) may be coupled between the first voltage node (n1) and the second voltage node (n2), and also, the second transistor (T2) may be coupled between the second voltage node (n2) and the third voltage node (n3) that is coupled to the second voltage node (n2).

In various implementations, the first voltage node (n1) may comprise a ground voltage supply (VSS or GND), such as, e.g., a ground supply rail, and the second voltage node (n2) may comprise an intermediate voltage supply (VSS_INT) based on the ground voltage supply (VSS or GND). Also, the intermediate voltage supply (VSS_INT) may be referred to as an intermediate power supply rail. Also, in various instances, the second transistor (T2) may operate to add capacitance to the intermediate voltage supply (VSS_INT) at the second voltage node (n2).

In various implementations, the footer based power-gate structure 404 may be coupled to power-gated circuitry 418, wherein the power-gated circuitry 418 is coupled between the intermediate voltage supply (VSS_INT) at the second voltage node (n2) and the positive voltage supply (VDD) at node (n4). Therefore, the footer based power-gate structure 404 may be used to power-gate the power-gated circuitry 418 via the first voltage node (n1) and the second voltage node (n2) with the ground voltage supply (VSS). Also, in some implementations, in reference to buried power rail (BPR) technology, one or more of the voltage supply nets (e.g., n1, n2, n3, n4) may be buried so as to comprise a buried voltage supply net, a buried power rail, or similar.

In some implementations, the first transistor (T1) and the second transistor (T2) may include a split-gate (SG) configuration 408 such that a gate of the first transistor (T1) is coupled to a control signal, such as, e.g., footer control signal (FTR_CTRL), and such that a gate of the second transistor (T2) is coupled to the third voltage node (n3). In some instances, the second transistor (T2) is coupled together to operate as a capacitor. Also, in some instances, as shown in FIG. 4, the footer based power-gate structure 404 may comprise a footer (FTR) that operates to power-gate a circuit, such as, e.g., the power-gated circuitry 418 by way of footer control signal (FTR_CTRL) that is used to activate and deactivate the first transistor (T1). Also, the footer control signal (FTR_CTRL) may be coupled to the gate of the first transistor (T1).

In various implementations, as shown in FIG. 4, the first transistor (T1) may comprise a P-type transistor, and the second transistor (T2) may be an N-type transistor, and also, the first transistor (T1) and the second transistor (T2) may be formed with a complementary field effect transistor (CFET) technology such that the P-type transistor (T1) is physically disposed on the N-type transistor (T2) in a P-over-N (PN) configuration or such that the N-type transistor is physically disposed on the P-type transistor in an N-over-P (NP) configuration, in various circuit based applications. However, various other configurations may be used and/or implemented to achieve similar results and/or behavior, wherein in some instances, the N-type transistor is physically disposed on the P-type transistor in an N-over-P (NP) configuration.

In some implementations, as shown in FIG. 4, the footer based power-gate structure 404 may be implemented with a multi-transistor structure, such as, e.g., a two-transistor (2T) related structure. Also, the multi-transistor structure may be configured a P-type metal-oxide-semiconductor (PMOS) transistor as the first transistor (T1) and an N-type MOS (NMOS) transistor as the second transistor (T2). Also, the first transistor (T1) may refer to a P-type field-effect transistor (PFET), and the second transistor (T2) refer to an N-type FET (NFET) transistor. However, various other configurations may be used to achieve similar results, behaviors and/or characteristics.

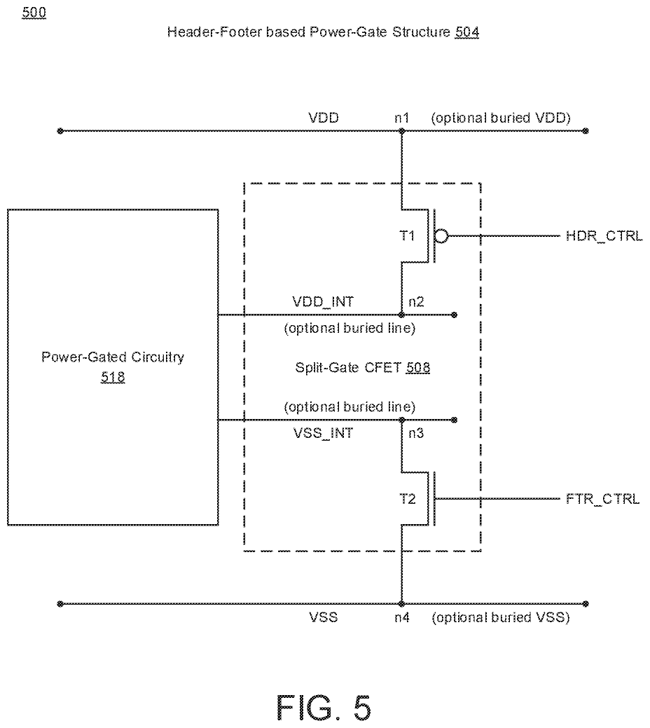

FIG. 5 illustrates a diagram 500 of header-footer based power-gate structure 504 for a circuit 518 in accordance with various implementations described herein.

In various implementations, the header-footer based power-gate structure 504 may provide for fabricating multi-transistor related circuitry with various integrated circuit (IC) components that are arranged and/or coupled together as an assemblage or some combination of parts that may provide for physical circuit designs and structures. In some instances, a method of designing, providing and fabricating the power-gate structure 504 as an integrated device may involve use of various circuit components and/or related structures described herein so as to implement various multi-transistor bitcell techniques associated therewith. Also, the power-gate structure 504 may be integrated with various circuitry and/or related components on a single chip, and also, the power-gate structure 504 may be implemented in some embedded devices for automotive, mobile, computer, server and/or Internet-of-Things (IoT) based applications.

As shown in FIG. 5, the header-footer based power-gate structure 504 may include a plurality of transistors (e.g., T1, T2), including, e.g., the first transistor (T1) and the second transistor (T2) that are arranged and coupled together so as to operate and/or function as a multi-transistor power-gate structure, such as a 2-transistor (2T) power-gate structure for various circuit related applications. In various applications, the first transistor (T1) may be coupled between a first voltage node (n1) and a second voltage node (n2), and also, the second transistor (T2) may be coupled between a third voltage node (n3) and a fourth voltage node (n4). Also, in reference to buried power rail (BPR) technology, one or more of the voltage supply nets (e.g., n1, n2, n3, n4) may be buried so as to comprise a buried voltage supply net, a buried power rail, or similar.

In various implementations, the header-footer based power-gate structure 504 may have the first transistor (T1) as a header transistor and the second transistor (T2) as a footer transistor. Also, header transistor (T1) may be coupled between positive voltage supply (VDD) at first voltage node (n1) and a first intermediate voltage supply (VDD_INT) at second voltage node (n2) based on the positive voltage supply (VDD). Also, the footer transistor (T2) may be coupled between ground voltage supply (VSS or GND) at fourth voltage node (n4) and a second intermediate voltage supply (VSS_INT) at third voltage node (n3) based on the ground voltage supply (VSS_GND).

In some implementations, the first voltage node (n1) may comprise a positive voltage supply (VDD), such as, e.g., a positive power supply rail, and the second voltage node (n2) may comprise first intermediate voltage supply (VDD_INT) based on positive voltage supply (VDD). Also, first intermediate voltage supply (VDD_INT) may be referred to as a first intermediate power supply rail. Also, fourth voltage node (n4) may comprise a ground voltage supply (VSS or GND), such as, e.g., a ground supply rail, and the third voltage node (n3) may comprise second intermediate voltage supply (VSS_INT) based on ground voltage supply (VSS or GND). Also, the second intermediate voltage supply (VSS_INT) may be referred to as a second intermediate power supply rail.

In various implementations, the header-footer based power-gate structure 504 may be coupled to power-gated circuitry 518, wherein the power-gated circuitry 518 may be coupled between first intermediate voltage supply (VDD_INT) at second voltage node (n2) and second intermediate voltage supply (VSS_INT) at third voltage node (n3). Thus, the header-footer based power-gate structure 504 may be used to power-gate the power-gated circuitry 518 via the first voltage node (n1) and the second voltage node (n2) with the positive voltage supply (VDD). Also, the header-footer based power-gate structure 504 may be used to power-gate the power-gated circuitry 518 via the third voltage node (n3) and the fourth voltage node (n4) with the ground voltage supply (VSS). Also, in some implementations, in reference to buried power rail (BPR) technology, one or more of the voltage supply nets (e.g., n1, n2, n3, n4) may be buried so as to comprise a buried voltage supply net, a buried power rail, or similar.

In some implementations, the first transistor (T1) and the second transistor (T2) may include a split-gate (SG) configuration 508 such that the first transistor (T1) is coupled to a first control signal, such as, e.g., header control signal (HDR_CTRL), and also such that the second transistor (T2) is coupled to a second control signal, such as, e.g., footer control signal (FTR_CTRL). In some instances, as shown in FIG. 5, the header-footer based power-gate structure 504 may comprise a header (HDR) that operates to power-gate a circuit, such as, e.g., the power-gated circuitry 518 by way of header control signal (HDR_CTRL) that is used to activate and deactivate first transistor (T1), wherein header control signal (HDR_CTRL) may be coupled to a gate of first transistor (T1). Also, in some instances, as shown in FIG. 5, the header-footer based power-gate structure 504 may comprise a footer (FTR) that operates to power-gate a circuit, such as, e.g., the power-gated circuitry 518 by way of footer control signal (FTR_CTRL) that is used to activate and deactivate second transistor (T2), wherein footer control signal (FTR_CTRL) may be coupled to a gate of second transistor (T2).

Also, in various implementations, the header control signal (HDR_CTRL) may be different than the footer control signal (FTR_CTRL). As such, the header control signal (HDR_CTRL) may be used to separately power-gate the power-gated circuitry 518 by way of the header control signal (HDR_CTRL), and in addition, the footer control signal (FTR_CTRL) may be used to separately power-gate the power-gated circuitry 518 by way of the footer control signal (FTR_CTRL).

In various implementations, as shown in FIG. 5, the first transistor (T1) may comprise a P-type transistor, and the second transistor (T2) may be an N-type transistor, and also, the first transistor (T1) and the second transistor (T2) may be formed with a complementary field effect transistor (CFET) technology such that the P-type transistor (T1) is physically disposed on the N-type transistor (T2) in a P-over-N (PN) configuration or such that the N-type transistor is physically disposed on the P-type transistor in an N-over-P (NP) configuration, in various circuit based applications. However, various other configurations may be used and/or implemented to achieve similar results and/or behavior, wherein in some instances, the N-type transistor is physically disposed on the P-type transistor in an N-over-P (NP) configuration.

In some implementations, as shown in FIG. 5, the header based power-gate structure 504 may be implemented with a multi-transistor structure, such as, e.g., a two-transistor (2T) related structure. Also, the multi-transistor structure may be configured a P-type metal-oxide-semiconductor (PMOS) transistor as the first transistor (T1) and an N-type MOS (NMOS) transistor as the second transistor (T2). Also, the first transistor (T1) may refer to a P-type field-effect transistor (PFET), and the second transistor (T2) refer to an N-type FET (NFET) transistor. However, various other configurations may be used to achieve similar results, behaviors and/or characteristics.

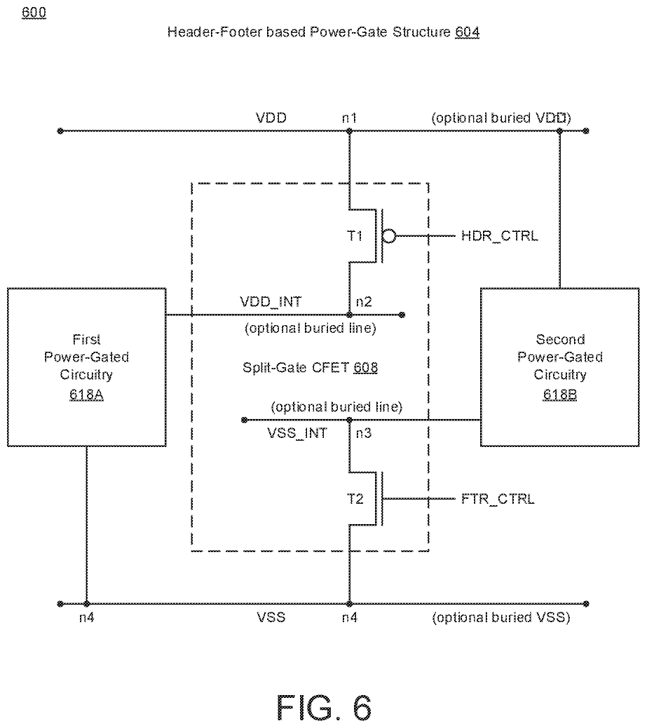

FIG. 6 illustrates a diagram 600 of header-footer based power-gate structure 604 for multiple circuits 618A, 618B in accordance with implementations described herein.

In various implementations, the header-footer based power-gate structure 604 may provide for fabricating multi-transistor related circuitry with various integrated circuit (IC) components that are arranged and/or coupled together as an assemblage or some combination of parts that may provide for physical circuit designs and structures. In some instances, a method of designing, providing and fabricating the power-gate structure 604 as an integrated device may involve use of various circuit components and/or related structures described herein so as to implement various multi-transistor bitcell techniques associated therewith. Also, the power-gate structure 604 may be integrated with various circuitry and/or related components on a single chip, and also, the power-gate structure 604 may be implemented in some embedded devices for automotive, mobile, computer, server and/or Internet-of-Things (IoT) based applications.

As shown in FIG. 6, the header-footer based power-gate structure 604 may include a plurality of transistors (e.g., T1, T2), including, e.g., the first transistor (T1) and the second transistor (T2) that are arranged and coupled together so as to operate and/or function as a multi-transistor power-gate structure, such as a 2-transistor (2T) power-gate structure for various circuit related applications. In various applications, the first transistor (T1) may be coupled between the first voltage node (n1) and the second voltage node (n2), and also, the second transistor (T2) may be coupled between the third voltage node (n3) and the fourth voltage node (n4). Also, in various instances, in reference to buried power rail (BPR) technology, one or more of the voltage supply nets (n1, n2, n3, n4) may be buried so as to comprise a buried voltage supply net, a buried power rail, or similar.

In various implementations, the header-footer based power-gate structure 604 may have the first transistor (T1) as a header transistor and the second transistor (T2) as a footer transistor. Also, header transistor (T1) may be coupled between positive voltage supply (VDD) at first voltage node (n1) and first intermediate voltage supply (VDD_INT) at second voltage node (n2) based on the positive voltage supply (VDD). Also, the footer transistor (T2) may be coupled between ground voltage supply (VSS or GND) at fourth voltage node (n4) and second intermediate voltage supply (VSS_INT) at third voltage node (n3) based on the ground voltage supply (VSS_GND).

In some implementations, the first voltage node (n1) may comprise a positive voltage supply (VDD), such as, e.g., a positive power supply rail, and the second voltage node (n2) may comprise first intermediate voltage supply (VDD_INT) based on positive voltage supply (VDD). Also, first intermediate voltage supply (VDD_INT) may be referred to as a first intermediate power supply rail. Also, fourth voltage node (n4) may comprise a ground voltage supply (VSS or GND), such as, e.g., a ground supply rail, and the third voltage node (n3) may comprise second intermediate voltage supply (VSS_INT) based on ground voltage supply (VSS or GND). Also, the second intermediate voltage supply (VSS_INT) may be referred to as a second intermediate power supply rail.

In various implementations, the header-footer based power-gate structure 604 may be coupled to multiple circuits, including first power-gated circuitry 618A and second power-gated circuitry 618B. In some instances, the first power-gated circuitry 618A may be coupled between first intermediate voltage supply (VDD_INT) at second voltage node (n2) and the ground voltage supply (VSS or GND) at the fourth voltage node (n4). Also, in some instances, the second power-gated circuitry 618B may be coupled between the second intermediate voltage supply (VSS_INT) at third voltage node (n3) and the positive voltage supply (VDD) at the first voltage node (n1). Thus, the header-footer based power-gate structure 604 may be used to power-gate multiple power-gated circuits 618A, 618B via first and second voltage nodes (n1, n2) with positive voltage supply (VDD) and via third and fourth voltage nodes (n3, n4) with ground voltage supply (VSS or GND). Also, in some implementations, in reference to buried power rail (BPR) technology, one or more of the voltage supply nets (e.g., n1, n2, n3, n4) may be buried so as to comprise a buried voltage supply net, a buried power rail, or similar.

In some implementations, the first transistor (T1) and the second transistor (T2) may include a split-gate (SG) configuration 608 such that the first transistor (T1) is coupled to a first control signal, such as, e.g., header control signal (HDR_CTRL), and also such that the second transistor (T2) is coupled to a second control signal, such as, e.g., footer control signal (FTR_CTRL). In some instances, as shown in FIG. 6, the header-footer based power-gate structure 604 may comprise a header (HDR) that operates to power-gate a first circuit, such as, e.g., first power-gated circuitry 618A by way of header control signal (HDR_CTRL) that is used to activate and deactivate first transistor (T1), wherein header control signal (HDR_CTRL) may be coupled to a gate of first transistor (T1). Also, in some instances, as shown in FIG. 6, the header-footer based power-gate structure 604 may comprise a footer (FTR) that operates to power-gate a second circuit, such as, e.g., second power-gated circuitry 618B by way of footer control signal (FTR_CTRL) that is used to activate and deactivate second transistor (T2), wherein footer control signal (FTR_CTRL) may be coupled to a gate of second transistor (T2).

Also, in various implementations, the header control signal (HDR_CTRL) may be different than the footer control signal (FTR_CTRL). As such, the header control signal (HDR_CTRL) may be used to separately power-gate the first power-gated circuitry 618A by way of the header control signal (HDR_CTRL), and in addition, the footer control signal (FTR_CTRL) may be used to separately power-gate the second power-gated circuitry 618B by way of the footer control signal (FTR_CTRL).

In various implementations, as shown in FIG. 6, the first transistor (T1) may comprise a P-type transistor, and the second transistor (T2) may be an N-type transistor, and also, the first transistor (T1) and the second transistor (T2) may be formed with a complementary field effect transistor (CFET) technology such that the P-type transistor (T1) is physically disposed on the N-type transistor (T2) in a P-over-N (PN) configuration or such that the N-type transistor is physically disposed on the P-type transistor in an N-over-P (NP) configuration, in various circuit based applications. However, various other configurations may be used and/or implemented to achieve similar results and/or behavior, wherein in some instances, the N-type transistor is physically disposed on the P-type transistor in an N-over-P (NP) configuration.

In some implementations, as shown in FIG. 6, the header based power-gate structure 604 may be implemented with a multi-transistor structure, such as, e.g., a two-transistor (2T) related structure. Also, the multi-transistor structure may be configured a P-type metal-oxide-semiconductor (PMOS) transistor as the first transistor (T1) and an N-type MOS (NMOS) transistor as the second transistor (T2). Also, the first transistor (T1) may refer to a P-type field-effect transistor (PFET), and the second transistor (T2) refer to an N-type FET (NFET) transistor. However, various other configurations may be used to achieve similar results, behaviors and/or characteristics.

It should be intended that the subject matter of the claims may not be limited to the implementations and illustrations provided herein, but include modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. Moreover, it should be appreciated that such a development effort may be complex and time consuming, but would nevertheless be a routine undertaking of design, fabrication, and manufacture for those of ordinary skill having benefit of this disclosure.

Described herein are various implementations of a device with a power-gate structure having multiple transistors including a first transistor and a second transistor. The first transistor may be coupled between a first voltage node and a second voltage node, and the second transistor may be coupled between the second voltage node and a third voltage node that is coupled to the second voltage node. Also, the first transistor comprises a P-type transistor, and the second transistor comprises an N-type transistor. Also, the first transistor and the second transistor are formed with a complementary field effect transistor (CFET) technology such that the P-type transistor is physically disposed on the N-type transistor in a P-over-N (PN) configuration or such that the N-type transistor is physically disposed on the P-type transistor in an N-over-P (NP) configuration.

Described herein are various implementations of a device with a power-gate structure having a header transistor and a footer transistor. The header transistor may be coupled between a positive voltage supply and a first intermediate voltage supply based on the positive voltage supply, and the footer transistor may be coupled between a ground voltage supply and a second intermediate voltage supply based on the ground voltage supply. Also, the header transistor comprises a P-type transistor, and the footer transistor comprises an N-type transistor. Also, the header transistor and the footer transistor are formed with a complementary field effect transistor (CFET) technology such that the P-type transistor is physically disposed on the N-type transistor in a P-over-N (PN) configuration or such that the N-type transistor is physically disposed on the P-type transistor in an N-over-P (NP) configuration.

Described herein are various implementations of a method that couples a first transistor between a first voltage node and a second voltage node. Also, the method may couple a second transistor between the second voltage node and a third voltage node. Also, the method may couple the second voltage node to the third voltage node. Also, the first transistor comprises a P-type transistor, and the second transistor comprises an N-type transistor. Also, the first transistor and the second transistor are formed with a complementary field effect transistor (CFET) technology such that the P-type transistor is physically disposed on the N-type transistor in a P-over-N configuration or such that the N-type transistor is physically disposed on the P-type transistor in an N-over-P (NP) configuration.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In some other instances, well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various related techniques described herein, other and further implementations may be devised in accordance with the disclosure herein, which may be determined by the claims that follow.

Although the subject matter has been described herein in language specific to structural features and/or methodological acts, it should be understood that the subject matter defined in the appended claims is not necessarily limited to the specific features or acts described above. Rather, specific features and acts described above are disclosed as example forms of implementing the claims.

What is claimed is:

1. A device comprising:
a power-gate structure having multiple transistors including a first transistor and a second transistor,
wherein the first transistor is coupled between a first voltage node and a second voltage node,
wherein the second transistor is coupled between the second voltage node and a third voltage node that is coupled to the second voltage node,
wherein the first transistor comprises a P-type transistor,
wherein the second transistor comprises an N-type transistor, and
wherein the first transistor and the second transistor are formed with a complementary field effect transistor (CFET) technology such that the P-type transistor is physically disposed on the N-type transistor in a P-over-N (PN) configuration or such that the N-type transistor is physically disposed on the P-type transistor in an N-over-P (NP) configuration.

2. The device of claim 1, wherein:
the first voltage node comprises a positive voltage supply,
the second voltage node comprises an intermediate voltage supply based on the positive voltage supply, and
the second transistor operates to add capacitance to the intermediate voltage supply at the second voltage node.

3. The device of claim 2, wherein:
one or more of the positive voltage supply and the intermediate voltage supply comprises a buried power rail.

4. The device of claim 1, wherein:
the first voltage node comprises a ground voltage supply,
the second voltage node comprises an intermediate voltage supply based on the ground voltage supply, and
the first transistor operates to add capacitance to the intermediate voltage supply at the second voltage node.

5. The device of claim 4, wherein:
one or more of the ground voltage supply and the intermediate voltage supply comprises a buried power rail.

6. The device of claim 1, wherein the first transistor and the second transistor have a common-gate configuration such that the first transistor and the second transistor share a common gate that is coupled to a control signal.

7. The device of claim 1, wherein the first transistor and the second transistor have a split-gate configuration such that a gate of the first transistor is coupled to a control signal and such that a gate of the second transistor is coupled to the third voltage node.

8. The device of claim 1, wherein:
the power-gate structure comprises a header that operates to power-gate a circuit by way of a header control signal that is used to activate and deactivate the first transistor and the second transistor, and
the header control signal is coupled to gates of the first transistor and the second transistor.

9. The device of claim 1, wherein:
the power-gate structure comprises a header that operates to power-gate a circuit by way of a header control signal that is used to activate and deactivate the first transistor,
the header control signal is coupled to a gate of the first transistor, and
the third voltage node is coupled to a gate of the second transistor.

10. The device of claim 1, wherein:
the power-gate structure comprises a footer that operates to power-gate a circuit by way of a footer control signal that is used to activate and deactivate the first transistor and the second transistor, and
the footer control signal is coupled to gates of the first transistor and the second transistor.

11. The device of claim 1, wherein:
the power-gate structure comprises a footer that operates to power-gate a circuit by way of a footer control signal that is used to activate and deactivate the second transistor,
the footer control signal is coupled to a gate of the second transistor, and
the third voltage node is coupled to a gate of the first transistor.

12. A device comprising:
a power-gate structure having a header transistor and a footer transistor,
wherein the header transistor is coupled between a positive voltage supply and a first intermediate voltage supply based on the positive voltage supply,
wherein the footer transistor is coupled between a ground voltage supply and a second intermediate voltage supply based on the ground voltage supply,
the header transistor comprises a P-type transistor,
the footer transistor comprises an N-type transistor, and
the header transistor and the footer transistor are formed with a complementary field effect transistor (CFET) technology such that the P-type transistor is physically disposed on the N-type transistor in a P-over-N (PN) configuration or such that the N-type transistor is physically disposed on the P-type transistor in an N-over-P (NP) configuration.

13. The device of claim 12, wherein the first transistor and the second transistor have a split-gate configuration such that a gate of the first transistor is coupled to a header control signal and such that a gate of the second transistor is coupled to a footer control signal that is different than the header control signal.

14. The device of claim 12, wherein:
a header control signal is coupled to a gate of the header transistor, and
the header transistor operates to power-gate a circuit by way of the header control signal that is used to activate and deactivate the header transistor.

15. The device of claim 12, wherein:
a footer control signal is coupled to a gate of the footer transistor, and
the footer transistor operates to power-gate a circuit by way of the footer control signal that is used to activate and deactivate the footer transistor.

16. The device of claim 12, wherein:
a header control signal is coupled to a gate of the header transistor, and
the header transistor operates to power-gate a first circuit by way of the header control signal that is used to activate and deactivate the header transistor.

17. The device of claim 16, wherein:
a footer control signal is coupled to a gate of the footer transistor,
the footer transistor operates to power-gate a second circuit by way of the footer control signal that is used to activate and deactivate the footer transistor, and
the second circuit is different than the first circuit.

18. A method comprising:
coupling a first transistor between a first voltage node and a second voltage node,
coupling a second transistor between the second voltage node and a third voltage node;
coupling the second voltage node to the third voltage node,
the first transistor comprises a P-type transistor,
the second transistor comprises an N-type transistor, and
the first transistor and the second transistor are formed with a complementary field effect transistor (CFET) technology such that the P-type transistor is physically disposed on the N-type transistor in a P-over-N configuration or such that the N-type transistor is physically disposed on the P-type transistor in an N-over-P (NP) configuration.

19. The method of claim 18, wherein:
the first voltage node comprises a positive voltage supply,
the second voltage node comprises an intermediate voltage supply based on the positive voltage supply,
the second transistor operates to add capacitance to the intermediate voltage supply at the second voltage node, and
one or more of the first voltage node, the second voltage node and the third voltage node comprises a buried power rail.

20. The method of claim 18, wherein:
the first voltage node comprises a ground voltage supply,
the second voltage node comprises an intermediate voltage supply based on the ground voltage supply,
the first transistor operates to add capacitance to the intermediate voltage supply at the second voltage node. and
one or more of the ground voltage supply and the intermediate voltage supply comprises a buried power rail.
